(19) United States
(12) Patent Application Publication
(10) Pub. No.: US 2005/0061251 A1
(43) Pub. Date: Mar. 24, 2005

(54) Apparatus and method for metal plasma immersion ion implantation and metal plasma immersion ion deposition

(76) Inventors: Ronghua Wei, San Antonio, TX (US); Thomas Booker, San Antonio, TX (US); Christopher Rincon, San Antonio, TX (US); James Arps, San Antonio, TX (US)

Correspondence Address: O'KEEFE, EGAN & PETERMAN, L.L.P., Building C, Suite 200, 1101 Capital of Texas Highway South, Austin, TX, 78746, US

(21) Appl. No.: 10/932,925

(22) Filed: Sep. 2, 2004

Related U.S. Application Data
(60) Provisional application No. 60/499,566, filed on Sep. 2, 2003.

(51) Int. Cl. C23C 16/00; C23C 14/00

(52) U.S. Cl. 118/726; 427/523; 427/569

(57) ABSTRACT

This invention is a method for metal plasma ion implantation and metal plasma ion deposition, comprising: providing a vacuum chamber with at least one workpiece having a surface positioned on a worktable within the vacuum chamber; reducing the pressure in the vacuum chamber; generating a plasma of metal ions within the vacuum chamber, applying a negative bias to the worktable to thereby accelerate metal ions from the plasma toward at least one workpiece to thereby either implant metal ions into or deposit metal ions onto the workpiece or both. This invention includes an apparatus for metal ion implantation and metal ion plasma deposition, comprising: a vacuum chamber, a metal plasma generator within the vacuum chamber, and at least one worktable within the vacuum chamber.

This application claims priority to U.S. provisional application Ser. No. 60/499,566, filed Sep. 2, 2003, incorporated herein by reference.

### FIELD OF THE INVENTION

This invention pertains to an apparatus and a method for implantation (or deposition) of metal ions into (or onto) solid surfaces to improve their metallurgical and tribological properties.

### BACKGROUND OF THE INVENTION

Components often fail due to excessive wear, corrosion and fatigue and the failure can result in severe damage to the system in which the component serves, if not injury of operators. To combat wear corrosion and fatigue, and prolong the lifetime of components, various techniques have been used. One of them is the surface engineering of materials. Using this technique, the properties of the bulk material is preserved, but the surface where all the actions take place is treated so that it becomes harder to withstand wear, contains more alloying elements to fight corrosion, or experiences more compress stress to minimize fatigue failure. The commonly used methods in surface engineering include deposition of coatings onto, or implantation of ion species into, the surface.

Plasma Immersion Ion Implantation (PIII) and Plasma Immersion Ion Processing (PIIP) are two fairly new technologies. PIII is a process in which nitrogen or carbon ions, typically, are accelerated at a high energy (for instance, 50-100 keV) and then injected into the surface to form a layer of hard nitrides or carbides. In contrast, PIIP is a coating process in which ions are accelerated at a much lower energy (0.5-5 keV) and then deposited on the surface to form an “add-on” layer. Regardless of these differences, both have received significant attention because they share a significant advantage over conventional Beamline Ion Implantation (BII) and Ion Beam Assisted Deposition (IBAD) in that they are non line-of-sight processes by which complex surfaces can be treated without manipulation.

Though PIII and PIIP have advantages over conventional BII and IBAD, their applications have been limited to only the areas where a suitable precursor (gas) can be found. In particular, the ability to implant metal ion species or deposit metal-based coatings using these methods has been extremely difficult. Although some metal-containing precursors are available, many of them are air sensitive and flammable, and some are even pyrophoric, corrosive and dangerous to the health of the operators. In addition, many of these chemical compounds are also very expensive and it is nearly impossible to obtain a pure metal (such as Ti or Cr) or desired metal compound (such as TiN or CrN) from most precursors.

It occurs that, from BII studies, metal-ion implantation has shown advantages over gaseous ion implantation in various applications, such as for improving corrosion and wear resistance for dies and punches. However, beam ion implantation has significant limitations in term of large-scale production and treatment cost.

### SUMMARY OF THE INVENTION

This invention provides one or more solutions to the disadvantages and omissions of the discussed above. In this regard, this invention is an apparatus and a method by which the shortcomings of ion beam implantation, gas PIII and gas PIID can be overcome. The invention makes large-scale processing possible.

The invention employs a large scaled metal plasma immersion ion implantation (MPIII) and metal plasma immersion ion deposition (MPIID) technique that is employed to accomplish the treatment of surfaces to combat wear, corrosion, and fatigue. By using this apparatus and the method, a metal plasma is generated, extracted and implanted into or deposited onto three-dimensional components. Because this is a plasma process wherein the target sample is immersed in the plasma, no sample manipulation is necessary. This technology makes large scaled processing possible. As a result, the process cost can be reduced substantially.

In one broad respect, this invention is a method for metal plasma ion implantation and metal plasma ion deposition, comprising: providing a vacuum chamber with at least one workpiece having a surface positioned on a worktable within the vacuum chamber; reducing the pressure in the vacuum chamber; generating a metal plasma within the vacuum chamber, applying a negative bias to the worktable to thereby accelerate metal ions from the plasma toward the at least one workpiece to thereby either implant metal ions into or deposit metal ions onto the workpiece or both.

In this embodiment, the plasma can be generated by heating a metal in the vacuum chamber to form a metal vapor; and forming a metal plasma from the metal vapor. The method can include the generating radio frequency waves are within the vacuum chamber. Depending on the power used, the method can provide metal ion deposition, metal ion implantation, or both. In the method, the base pressure in the vacuum chamber can be less than 10⁻⁵ Torr. Optionally, the metal ions can be generated using a metal plasma generator which comprises a solenoid, a discharge chamber, a heatable crucible in which solid metal is placed, and a filament that emits electrons upon heating. In one embodiment, the workpiece is implanted or deposited with metal omnidirectionally. The worktable can be biased using a pulsed voltage supply.

In another broad respect, this invention is an apparatus for metal ion plasma implantation and metal ion plasma deposition, comprising: a vacuum chamber, a metal plasma generator within the vacuum chamber, and at least one worktable within the vacuum chamber. In this embodiment, the metal plasma generator may comprise a discharge chamber, a crucible which holds the metal, and a filament that produces electrons. The metal plasma generator may further comprise a solenoid that provides a magnetic field. The apparatus may also include a radio frequency wave generator within the vacuum chamber. The at least one worktable may have a negative bias, and may be supplied with power using a pulsed voltage supply. The vacuum chamber can have a base pressure of less than 10⁻⁵ Torr.

In another broad respect, this invention is a metal plasma generator, comprising a heatable crucible within a discharge chamber closed on one end, and a filament suspended over the crucible, wherein the cylindrical discharge chamber is surrounded by a solenoid. In this aspect of the invention the heatable crucible can be made of graphite, and the crucible can be embedded in a heater. The discharge chamber can be made of graphite. The solenoid may comprise metal tubing wrapped around a drum, wherein the drum can be formed from graphite or stainless steel. The crucible can be connected to a crucible power supply, wherein the discharge chamber is connected to a discharge chamber power supply, and wherein.

In another broad respect, this invention is a method of making an apparatus for metal ion plasma implantation and metal ion plasma deposition, comprising: providing a vacuum chamber, placing a metal ion plasma generator within the vacuum chamber, and placing at least one worktable within the vacuum chamber. In this embodiment, the metal ion plasma generator may comprise a discharge chamber, a crucible which holds the metal, and a filament that produces electrons. The metal plasma generator may further comprise a solenoid that provides a magnetic field. The apparatus may further comprise a radio frequency wave generator within the vacuum chamber. The worktable can be supplied with a negative bias, such as supplied by a high voltage pulse generator. The discharge chamber can be connected to a discharge chamber power supply, wherein the solenoid is connected to a solenoid power supply, wherein the worktable is connected to a pulsed voltage power supply, wherein the filament is connected to a filament power supply, and wherein the heatable crucible is connected to a crucible power supply.

Compared to the metal beam ion implantation, where only a small spot such as 2″ in diameter, flat samples can be advantageously treated, the apparatus disclosed herein is large scaled and an immersion process. Compared to the metal vacuum vapor arc (MAVVA) process, which is still a beam line-of-sight process, the process and apparatus of this invention can implant metal into parts having a three-dimensional geometry.

### BRIEF DESCRIPTION OF THE DRAWINGS

FIG. 1 illustrates a representative schematic of the system of this invention.

FIG. 2 illustrates a representative schematic of the metal plasma generator used in the system of this invention.

FIG. 3 illustrates a representative isometric drawing of the metal plasma generator.

FIG. 4 illustrates is an Auger depth profile for chromium (Cr) into silicon (Si) using the system and process of this invention.

FIG. 5 illustrates the energy dispersive spectrum of Ti implanted/deposited on Si on vertical strip using the system and process of this invention.

### DETAILED DESCRIPTION OF THE INVENTION

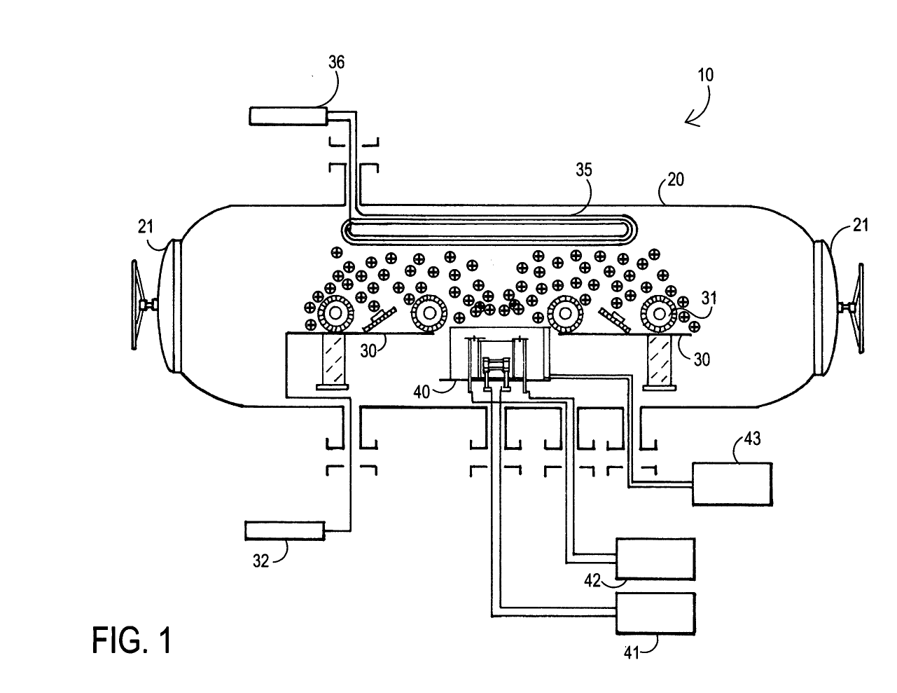

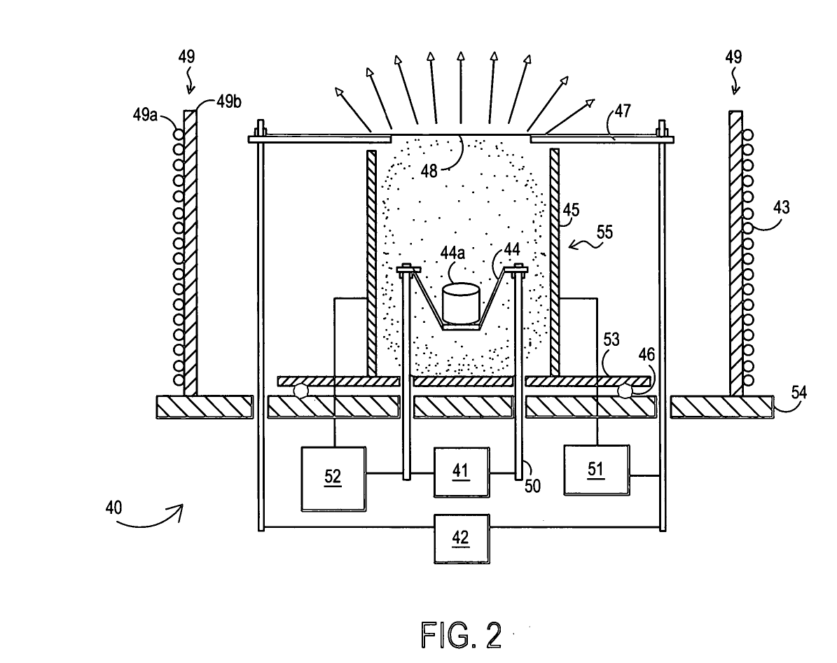

The apparatus and the method of this invention includes an apparatus that for metal plasma generation, metal plasma expansion, metal ion extraction, and metal ion implantation and/or metal ion deposition. The system is shown in FIG. 1. The metal plasma generator is schematically shown in FIG. 2. A metallic material such as chromium (Cr), titanium (Ti), molybdenum (Mo), zinc (Zn), nickel (Ni), cadmium (Cd), gold (Au), silver (Ag), cobalt (Co), tin (Sn), copper (Cu), yttrium, combinations of metals, or non-metallic material such as B and Si is placed into the crucible, which can be heated through a heater. Virtually any metal can be used so long as it is capable of producing a metal vapor and metal plasma in the practice of this invention. Once the temperature reaches the melting point or sublimation point, metal vapor will fill in the discharge chamber of the ion source. When the filament, which can be made of a material such as tungsten, is supplied with an electrical current as to reach the thermionic emission temperature, metal electrons will be generated. With the discharge power supply bias on the discharge chamber, electrons emitted by the filament will be drawn to the discharge chamber wall, which can be made of carbon. On the way to the wall, they experience collisions with the metal atoms, thereby resulting in ionization of the metal atoms or clusters. A plasma plume forms inside and above the discharge chamber. The solenoid provides the ion source with magnetic field, which will enhance the plasma production. The optional auxiliary crucible power supply can assist the heater and allow a finer control of the evaporation process.

In FIG. 1, the system 10 includes a vacuum chamber 20. The vacuum chamber 20 can be made from a variety of materials and may be in a variety of three dimensional shapes and sizes. For example, the chamber can be made of metals and alloys that conduct electricity, including but not limited to steel, aluminum, iron, stainless steel, copper, and so on. The vacuum chamber 20 can have a variety of shapes including shapes such as an elongated cylinder, and having a square, rectangular, triangular, and square base, and so on. Since the vacuum chamber 20 is under a vacuum during the practice of this invention, the type of material and its thickness should be effective to enable the vacuum chamber 20 to retain its shape while under vacuum. In addition, the material may optionally conduct electricity. The vacuum chamber 20 may be made of one or more materials and may have one or more layers. The chamber may optionally be thermally insulated. The vacuum chamber may include one or more doors 21 to open or seal the vacuum chamber 20.

The vacuum chamber 20 also includes a worktable 30. For purposes of this invention, the legs, made of insulating materials such as ceramics, which support the worktable 30 are considered to be part of the worktable 30. The workpieces 31 to be treated are placed on the worktable 30. The worktable 30 can have one or more surfaces, such as having more than one shelf or stage on which to place workpieces (which can be devices or parts) to be treated. The worktable 30 can be made from a variety of electrically conductive materials, such as those used to make the vacuum chamber 20. The worktable 30 can be made in a variety of shapes and sizes. The worktable 30 may hold one or a plurality of workpieces 31 to be treated. The worktable is connected to a high voltage pulse generator 32 that supplies a negative bias voltage to the worktable 30. The worktable 30 is placed outside the ion source. The worktable 30 is attached via an appropriate line to a high voltage generator 32. The generator can be a pulsed generator. When the negative, optionally pulsed, voltage is applied, metal ions will be extracted from the plasma and accelerated to the surfaces of the components. The voltage can be a negative pulsed voltage. If the bias voltage is high, metal ion implantation is accomplished. If the bias voltage is low, metal ion deposition is performed. Alternatively, these two processes can be combined. For example, a high voltage implantation followed by the ion deposition will greatly enhance the coating adhesion. These high and low voltages will vary depending on the type of metal, workpieces to be treated, and so on. A pulsed voltage supply is preferably used as the pulse of voltage allows the sheath that develops around a work piece to be maintained at a small thickness to thereby allow ion implantation to follow the contour of parts. As is known to one of skill in the art, if the sheath is too large (such as develops using DC power), ion implantation is impeded and ions will not implant into or deposit onto the workpiece (such as a with respect to a gear or other device with complicated shapes). Arcing may also be minimized using a pulsed voltage supply. The pulse may vary depending on pulse frequency, pulse width, voltages, and type of workpiece. In general, 5 to 30 microsecond pulse widths are employed. If a reactive gas (for example, N, O and C) is introduced during the process, ceramic coatings (nitrides, oxides or carbides) can be achieved. It is also noted that the worktable can also be mounted on top of the antenna and the workpieces to be mounted at the bottom of the worktable. The negative bias can be supplied by a direct current (DC). In one embodiment, the worktable 30 is biased to have a potential in the range of, for example, 100 to 2,000 volts. By placing a negative bias on the worktable during the practice of this invention, positively charged nitrogen ions will be accelerated toward the worktable and the workpieces to be treated. As the metal ions drawn from the plasma bombard the workpieces, the temperature will rise. Typically, the temperature is monitored and, by adjusting the bias or current to the worktable and workpieces, maintained in a range from about 50 to about 500 degrees Centigrade, more typically from about 100 to 250 degrees Centigrade, and in one embodiment from about 150 to 250 degrees Centigrade, and in one specific embodiment about 200 degrees Centigrade. It should be appreciated that plasma generation can be formed using discharge power, ion extraction, ion energy selection, and temperature control of the crucible.

The workpieces 31 to be treated can be formed from a variety of materials or combination of materials. For example, the workpieces can be made of silicon, molybdenum, nickel, ceramic, iron, various steels, titanium, titanium alloy, and so on. Likewise, the shape and size of the workpieces may vary. Representative examples of such workpieces include but are not limited to gears, bearings, shafts, and so on.

An optional radio frequency (RF) antenna 35 is placed over the ion source inside the vacuum chamber. When the RF power is on, the plasma will spread out throughout the vacuum chamber. Likewise, it should be noted that neutral metal atoms and clusters, as well as ions, are produced by the metal ion generator 40. When the RF power is on, the RF waves may serve to ionize more metal vapor. The RF antenna 35 is powered by RF generator 36.

The vacuum chamber 20 also includes a vacuum line, not shown, that extends to a vacuum source, not shown, such as a vacuum pump. One or more vacuum lines can be used. Similarly, more than one vacuum pumps can be used to reduce the pressure in the vacuum chamber 20. The source of vacuum is capable of providing a vacuum in the chamber prior to processing of below 10⁻⁵ Torr. In one embodiment, the (base) pressure is reduced to about 2×10⁻⁶ Torr. Conventional vacuum pumps designed for this purpose can be used in the practice of this invention.

The vacuum chamber 20 includes a metal plasma generator 40. The metal plasma generator 40 is depicted in detail in FIG. 2. The metal plasma generator 40 is connected to crucible power supply 41, filament power supply 42, and solenoid power supply 43, and discharge power supply 51, each of which powers components of the metal plasma generator 40.

The metal plasma generator 40 includes a crucible 44 (powered by the crucible power supply 41), a discharge chamber 55 which can be made of carbon (graphite), insulation 46 (e.g., stand off legs) such as ceramic insulation that electrically insulates the discharge chamber 55, electrically conductive posts 47 that support the filament 48 which generates electrons, and a solenoid 49 which provides a magnetic field to increase neutral collisions of the electrons produced by the filament 48. The solenoid rests on the base 54, which can be made of stainless steel. The discharge chamber 55 is defined by the discharge chamber wall 45 and discharge chamber base 53.

The crucible 44 is heated so that the material vaporizes after reaching its melting point or sublimation point. Continued heating results in the discharge chamber 45 to fill with vapor of the material 44a in the crucible 44. The crucible 44 can be heated in a variety of ways. For example, a heating element can be applied to the crucible 44 to effect heating. For example, the crucible 44, which can be made of graphite, can be embedded in a metallic heater such as a tantalum heater, which functions to provide resistive heating. The crucible 44 would be heated by the heat from the tantalum heater. In this embodiment, the crucible power supply connects to the heater. Alternatively, the crucible 44 is heated with an electric current from the crucible power supply 41 through the electrically conductive supports 50 that attach to the crucible 44. Either AC or DC can be used. Alternatively, the crucible 44 can be heated by electrons in an argon plasma in the discharge chamber 55. In this regard, if positive voltage is applied to the crucible, electrons will be drawn to the material 44a which will thereby heat the crucible 44 and the material 44a. When a stabilized ionized metal vapor is formed, the argon inlet can be closed and additional metal vapor generation will be sustained.

The filament power supply 42, which supplies current to the filament 48 via the electrically conductive posts 47, is typically an alternating current power supply. During operation, after the filament 48 heats up due to, for example, an AC current, the filament 48 after reaching its thermionic emission temperature emits electrons into the vacuum chamber 20 and discharge chamber 55. The electrons impact metal vapor in the discharge chamber 55 which generates a plasma (metal ions and electrons) through electron neutral impact ionization. The metal ions formed in the discharge chamber 55 are emitted into the vacuum chamber 20 and optionally spread out in the chamber through the action of the RF antenna 35. In addition, the solenoid 49, which is powered by the solenoid power supply 43, provides a magnetic field which causes electrons emitted by the filament 48 to impact more metal vapor owing to having an increased electron-neutral collisions. The solenoid 49 can be supported and electrically isolated (to prevent shorting the connection) metal tubing 49a or metal wiring, such as copper coil, wrapped around a metal such as stainless steel drum 49b. If the solenoid 49 is made from tubing, water or other liquid can be run through the tubing to provide cooling. Use of the solenoid 49 allows ions to be generated more easily. A voltage (e.g., in the range from 30-150 volts) may be applied to the walls of the discharge chamber 55 via discharge power supply 51 to cause electrons to be drawn to the walls of the chamber.

During use, the vacuum chamber 20 is pumped down to a base pressure (such as 2×10⁻⁶ Torr). Next, the crucible 44 is heated to thereby produce metal vapors. If desired, an auxiliary (secondary) power supply 52 can be employed to assist the heating of the crucible 44, which may allow finer control of metal vapor production. The filament 48 is powered to generate electrons that impact the metal vapor to thereby produce metal ions. The solenoid 49, if used, may improve the efficacy of metal plasma ion production. The plasma of metal ions is emitted from the discharge chamber 55 into the balance the vacuum chamber 20 (it should be appreciated that the discharge chamber 55 is also under vacuum and within the vacuum chamber 20). When a DC voltage, such as in the range of 30-150 V, is applied between the electron source and the discharge chamber 55, electrons will be drawn to the chamber wall. Due to the electron-gas collisions, ionization of the metal occurs and plasma forms. The plasma plume forms inside and above the discharge chamber 55, and grows to fill the vacuum chamber. The RF from the RF antenna 35 serves to spread out the metal ion plasma through the vacuum chamber 20. If a negative bias voltage, such as at about 100-2000 V, is applied to the worktable 30 on which the workpieces 31 are placed in the plasma, metal ions will be accelerated toward to the components. In this way deposition occurs. Due to the ion bombardment, the temperature of the components will increase. In one embodiment, when the temperature of the worktable reaches a desired temperature point, the bias voltage or the current to the worktable 40 can be adjusted to maintain the temperature. In general, the metal ions impact the workpieces omnidirectionally. If a pulsed negative bias voltage is applied to the parts, at a high voltage, implantation occurs, while at low voltage, ion deposition occurs.

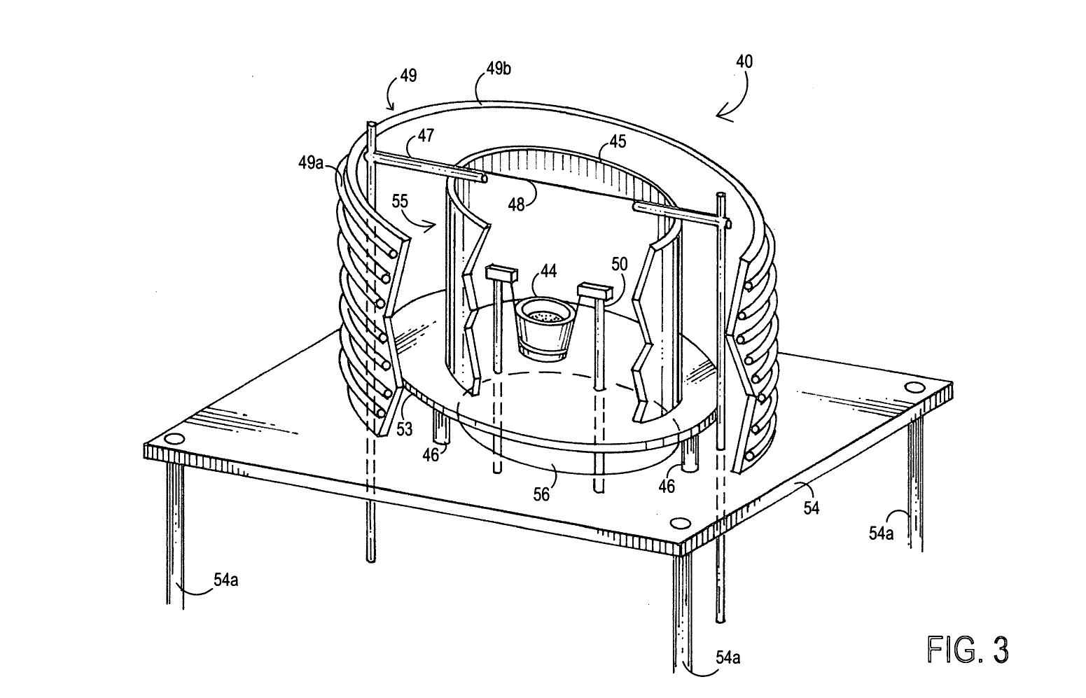

The metal plasma ion generator 30 is also depicted in an isometric, cut-away view in FIG. 3. The discharge chamber wall 45 rests on discharge chamber base 53, and together define the discharge chamber 55. Like the cylindrical discharge chamber wall 45, the discharge chamber base 53 may be made of graphite. The cylindrical discharge chamber wall 45 and discharge chamber base 53 together form a cylindrical structure with one closed end. The cylindrical discharge chamber wall 45 and base 53 may be connected together if desired, or the discharge chamber wall 45 may simply rest on the discharge chamber base 53. The discharge chamber base 53 may be supported by insulating (e.g., ceramic) stand off supports 46. The solenoid rests on the base 54, which optionally includes a hole 56 below the discharge chamber 45. The base 54 can be made, for example, of stainless steel. The base 54 may optionally include legs 54a to support the metal ion plasma generator 30 within the vacuum chamber 20. The solenoid tubing 49a is isolated from the steel base 54.

In FIG. 3, the solenoid 49 is shown which includes a cylindrical wall 49b and wrapped tubing 49a that is wrapped around the wall 49b. The tubing 49a can be supplied with water to provide cooling. The solenoid 49 rests on the stainless steel base 54. If desired, the solenoid 49 can be physically attached (bonded) to the base 54.

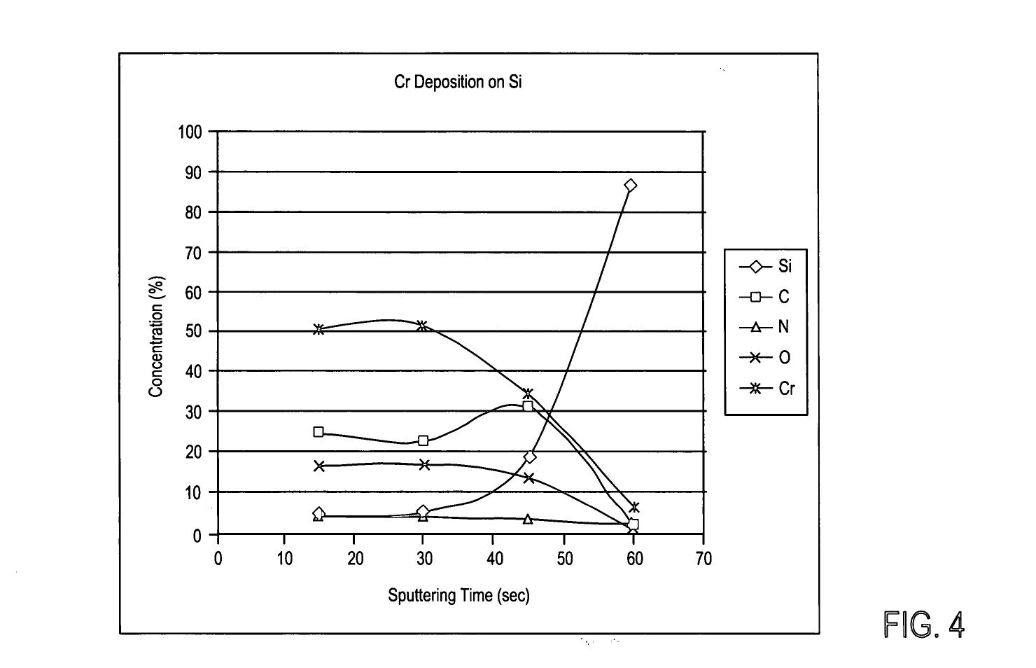

The system 10 discussed above was used to implant chromium (Cr) into silicon (Si) parts. The resulting parts were then examined. FIG. 4. is an Auger depth profile for Cr into Si using the system 10 of this invention on silicon workpieces. The deposited Cr layer with some implantation effect is clearly seen.

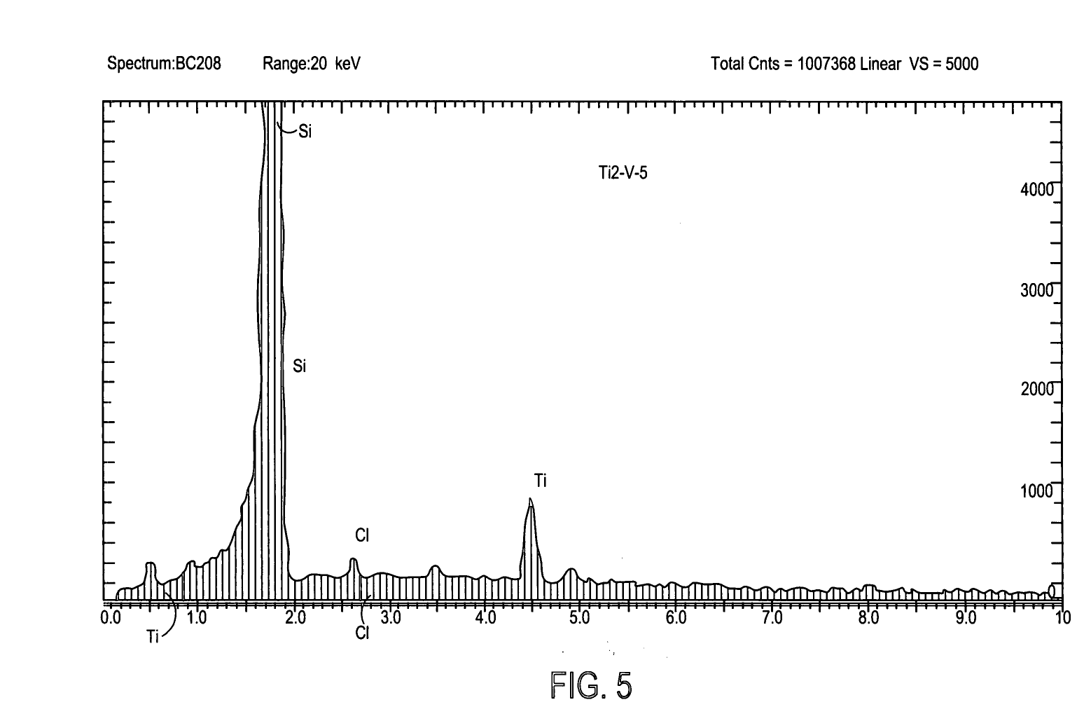

A silicon strip was treated with titanium using the system of this invention. FIG. 5 shows the results. In particular, FIG. 5 shows the energy dispersive spectrum of Ti implanted/deposited on Si on vertical strip.

1. A method for metal plasma ion implantation and metal plasma ion deposition, comprising: providing a vacuum chamber with at least one workpiece having a surface positioned on a worktable within the vacuum chamber; reducing the pressure in the vacuum chamber; generating a metal plasma within the vacuum chamber, applying a negative bias to the worktable to thereby accelerate metal ions from the plasma toward the at least one workpiece to thereby either implant metal ions into or deposit metal ions onto the workpiece or both.

2. The method of claim 1, wherein the metal ions are generated by heating a metal in the vacuum chamber to form a metal vapor; and forming a metal plasma from the metal vapor.

3. The method of claim 2 wherein radio frequency waves are generated within the vacuum chamber.

4. The method of claim 1 wherein metal ion deposition occurs.

5. The method of claim 1 wherein metal ion implantation occurs.

6. The method of claim 1 wherein metal ion deposition and metal ion implantation occur.

7. The method of claim 1 wherein the pressure is reduced to less than 10⁻⁵ Torr.

8. The method of claim 1 wherein the metal ions are generated using a metal plasma generator comprises a solenoid, a discharge chamber, a heatable crucible in which solid metal is placed, and a filament that emits electrons upon heating.

9. The method of claim 1 wherein the workpiece is formed from silicon.

10. The method of claim 1 wherein the metal is chromium, titanium, or yttrium.

11. The method of claim 1 wherein the workpiece is implanted or deposited with metal omnidirectionally.

12. The method of claim 1 wherein the worktable is biased using a pulsed voltage supply.

13. An apparatus for metal ion implantation and metal ion plasma deposition, comprising: a vacuum chamber, a metal plasma generator within the vacuum chamber, and at least one worktable within the vacuum chamber.

14. The apparatus of claim 13, wherein the metal plasma generator comprises a discharge chamber, a heatable crucible which holds the metal, and a filament that produces electrons.

15. The apparatus of claim 14, wherein the metal plasma generator further comprises a solenoid that provides a magnetic field.

16. The apparatus of claim 13, further comprising a radio frequency wave generator within the vacuum chamber.

17. The apparatus of claim 13, wherein the at least one worktable has a negative bias.

18. The apparatus of claim 17, wherein the negative bias is supplied by a pulsed voltage supply.

19. The apparatus of claim 17, wherein the vacuum chamber is under a pressure of less than 10⁻⁵ Torr.

20. A metal plasma generator, comprising a heatable crucible within a discharge chamber closed on one end, and a filament suspended over the crucible, wherein the cylindrical discharge chamber is surrounded by a solenoid that surrounds the discharge chamber.

21. The metal plasma generator of claim 20, wherein the heatable crucible is made of graphite, and the crucible is heated using a heater.

22. The metal plasma generator of claim 20, wherein the discharge chamber is made of graphite.

23. The metal plasma generator of claim 20, wherein the solenoid comprises metal tubing wrapped around a drum.

24. The metal plasma generator of claim 23, wherein the drum can be formed from graphite or stainless steel.

25. The metal plasma generator of claim 20, wherein the heatable crucible is connected to a crucible power supply, wherein the discharge chamber is connected to a discharge chamber power supply.

26. A method of making an apparatus for metal ion implantation and metal ion plasma deposition, comprising: providing a vacuum chamber, placing a metal plasma generator within the vacuum chamber, and placing at least one worktable within the vacuum chamber.

27. The apparatus of claim 26, wherein the metal plasma generator comprises a discharge chamber, a crucible which holds the metal, and a filament that produces electrons.

28. The apparatus of claim 27, wherein the metal plasma generator further comprises a solenoid that provides a magnetic field.

29. The apparatus of claim 26, further comprising a radio frequency wave generator within the vacuum chamber.

30. The apparatus of claim 26, wherein the at least one worktable has a negative bias.

31. The apparatus of claim 30, wherein the negative bias is supplied by a high voltage pulse generator.

32. The apparatus of claim 30, wherein the negative bias is supplied by a direct current voltage generator.

33. The apparatus of claim 27, wherein the discharge chamber is connected to a discharge chamber power supply, wherein the solenoid is connected to a solenoid power supply, wherein the worktable is connected to a pulsed or a direct current voltage power supply, wherein the filament is connected to a filament power supply, and wherein the heatable crucible is connected to a crucible power supply.
